(19) United States
(12) Patent Application Publication
(10) Pub. No.: US 2008/0128877 A1
(43) Pub. Date: Jun. 5, 2008

(54) SEMICONDUCTOR DEVICE

(76) Inventors: Mikihiko Itoh, Tokyo (JP); Masaru Koyanagi, Tokyo (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 11/947,030

(22) Filed: Nov. 29, 2007

(30) Foreign Application Priority Data
Nov. 30, 2006 (JP) 2006-324474

(51) Int. Cl. H01L 23/495

(52) U.S. Cl. 257/676; 257/E23.031

(57) ABSTRACT

A semiconductor device of an aspect of the invention comprises a first internal lead provided in a lead frame, and a semiconductor chip which is mounted on the lead frame and has a plurality of first pads provided along a first side, wherein the first internal lead has a first wiring portion extending in a direction parallel to the first side, the first side is arranged to vertically overlap the first wiring portion, and the first pad is connected with the first wiring portion.

### CROSS-REFERENCE TO RELATED APPLICATIONS

This application is based upon and claims the benefit of priority from prior Japanese Patent Application No. 2006-324474, filed Nov. 30, 2006, the entire contents of which are incorporated herein by reference.

### BACKGROUND OF THE INVENTION

1. Field of the Invention

The present invention relates to a semiconductor device, and more particularly to a package device formed by using a lead frame.

2. Description of the Related Art

A package device formed of one or a plurality of semiconductor chips is mounted on an electronic device.

A demand for offering technical advantages in such a package device has been increased from year to year. Therefore, a consumption current of a semiconductor chip tends to increase, and an increase in a ground voltage and a reduction in a power supply voltage in a region apart from pads due to a wiring resistance in a chip occurs.

Therefore, performance of the package device is lowered, and the demand for offering technical advantages is not satisfied.

Further, with the offer of technical advantages in the package device, the number of pads provided on a semiconductor chip is also increased.

For example, when the semiconductor chip is mounted in a lead frame, lead wiring lines in the lead frame associated with the respective pads are connected with these pads through bonding wires. Therefore, the number of lead wiring lines also grows with the increase in the number of pads.

On the other hand, in a marketplace of portable electronic devices, e.g., mobile phones, a reduction in size of the package is demanded.

Therefore, the pads on the semiconductor chip are arranged to be biased toward a given side, and a lead wiring terminal of a package substrate thereby has a shape that is biased toward one direction.

Accordingly, arrangement of the lead wiring lines becomes complicated in the lead frame.

For stabilization of the ground voltage and the power supply voltage in the chip, a technology of devising a shape of a suspender pin of the lead frame extending in a diagonal direction of the semiconductor chip and using the suspender pin as a ground voltage or power supply voltage lead wiring line has been proposed (see, e.g., JP-A 2004-343151 (KOKAI)).

According to this technology, electroconductive ground connecting portions or power supply connecting portions are provided between the suspender pins (tie bars) supporting a tab on which the semiconductor chip is mounted and an internal lead, and these connecting portions can be connected with a plurality of ground or power supply voltage pads on the semiconductor chip through wire bonding.

In this case, an increase in a ground voltage or a reduction in a power supply voltage in the semiconductor chip can be suppressed. However, in the above-explained configuration, when the pads on the semiconductor chip are arranged to be biased in a given direction, arrangement of the lead wiring lines becomes very difficult.

### BRIEF SUMMARY OF THE INVENTION

A semiconductor device of an aspect of the invention comprises: a first internal lead provided in a lead frame; and a semiconductor chip which is mounted on the lead frame and has a plurality of first pads provided along a first side, wherein the first internal lead has a first wiring portion extending in a direction parallel to the first side, the first side is arranged to vertically overlap the first wiring portion, and the first pad is connected with the first wiring portion.

### BRIEF DESCRIPTION OF THE SEVERAL VIEWS OF THE DRAWING

FIG. 1 is a plan view showing an example of a basic structure of an embodiment according to the present invention;

FIG. 2 is a plan view showing an example of the basic structure of the embodiment according to the present invention;

FIG. 3 is a plan view showing a structure of a lead frame side;

FIG. 4 is a plan view showing a structure of a semiconductor chip side;

FIG. 5 is a plan view showing a structure of a semiconductor chip side according to a first modification; and

FIG. 6 is a plan view showing a structure of a semiconductor chip side according to a second modification.

### DETAILED DESCRIPTION OF THE INVENTION

Several modes for carrying out examples of the present invention will now be explained hereinafter in detail with reference to the accompanying drawings.

### 1. Outline

An embodiment according to the present invention relates to a package device formed by using a lead frame.

The lead frame is constituted of package internal and external lead wiring lines, i.e., internal leads which are arranged in a package (a frame) and external leads serving as external terminals.

The lead frame used in the example of the present invention is characterized in that the internal lead (a first internal lead) for a ground or power supply voltage has a wiring portion (a first wiring portion) extending along a direction parallel to one side (a first side) of a semiconductor chip on which ground or power supply voltage pads are provided.

As a result, two ground or power supply voltage pads (first pads) provided at both ends of one side (the first side) of the semiconductor chip can be connected with the first wiring portion extending along a direction parallel to the one side.

Therefore, an increase in a ground voltage or a reduction in a power supply voltage due to an internal wiring resistance of the semiconductor chip can be suppressed.

Accordingly, a reduction in performance of the package device can be suppressed.

Further, since the ground or power supply voltage internal lead structure is adopted, providing the single ground or power supply voltage internal lead can suffice even if two ground or power supply voltage pads are provided on one side.

Therefore, arrangement of the lead wiring lines of the lead frame can be simplified.

### 2. Embodiment

### (A) BASIC STRUCTURE OF LEAD FRAME

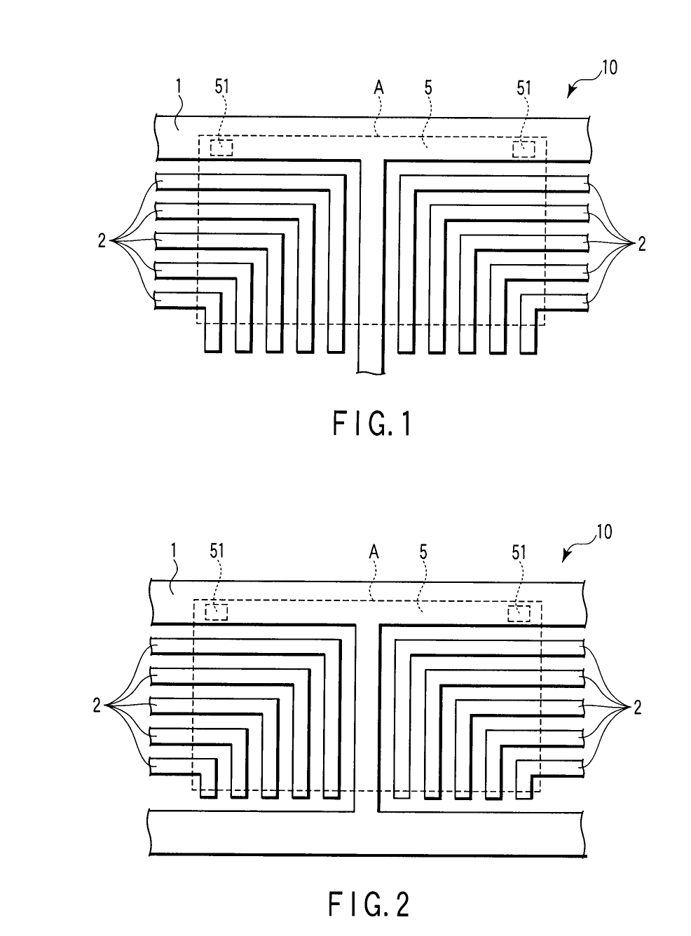

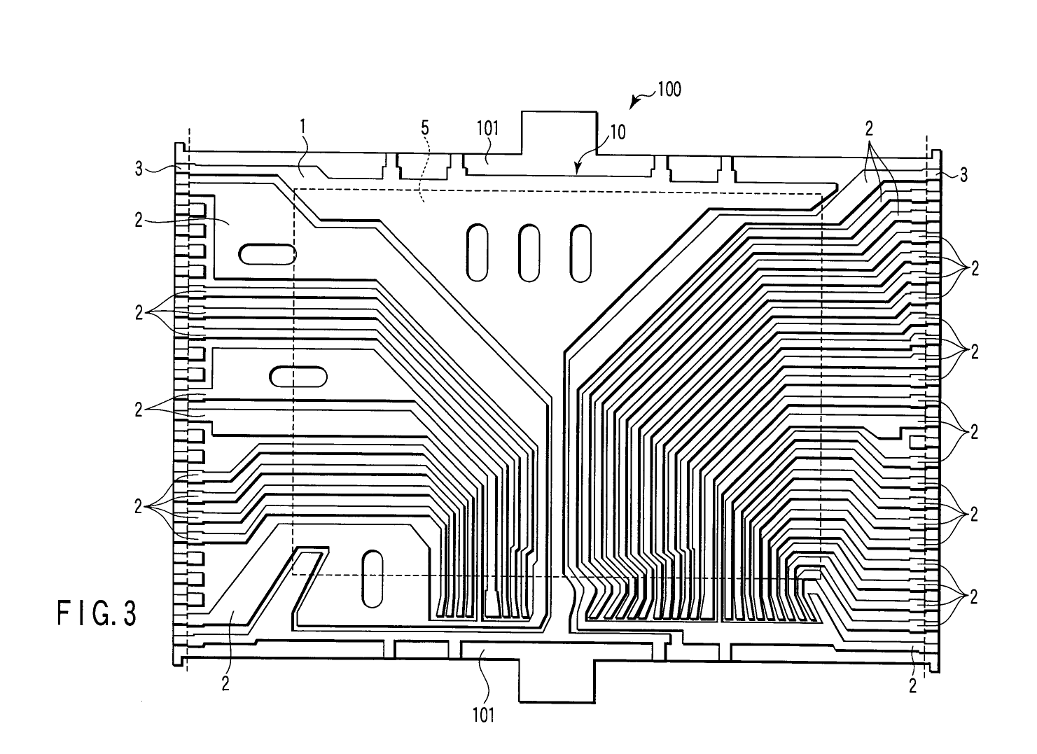

FIGS. 1 and 2 are plan views showing a basic structure of an internal lead of a lead frame used in an embodiment according to the present invention.

The embodiment according to the present invention is characterized in that a ground or power supply voltage internal lead has a wiring portion (a first wiring portion) arranged in parallel to one side of a semiconductor chip on which ground or power supply voltage pads are provided. Furthermore, this internal lead also has a wiring portion (a second wiring portion) extending from the part parallel to the one side of the semiconductor chip in a direction crossing one side of the semiconductor chip facing the side on which the ground or power supply pads are provided.

An example where the internal lead is a ground internal lead will now be explained hereinafter.

FIGS. 1 and 2 show a primary part of an internal lead in a lead frame 10, and depict a ground internal lead 1 and signal wiring internal leads 2. Moreover, a semiconductor chip 5 mounted on the lead frame and ground pads 51 provided on the semiconductor chip 5 are indicated by broken lines.

The ground internal lead 1 has a wiring portion parallel to one side of a semiconductor chip and a wiring portion extending in a direction crossing a side facing this side. As such a structural example, a T-shaped structure depicted in FIG. 1 or an H-shaped structure shown in FIG. 2 can be considered. Additionally, in such a case, an L-shaped structure is used for the signal wiring internal lead 2.

As a result, one side of the ground internal lead 1 can become parallel to one side of the semiconductor chip.

One side A of the semiconductor chip parallel to the ground internal lead 1 is one side of the semiconductor chip 5 on which the ground pads 51 are provided. Each ground pad 51 is formed of an electroconductive material and provided on the semiconductor chip 5 at both ends of this side A.

Since the ground internal lead 1 is parallel to the side on which the ground pads 51 are provided in this manner, the two ground pads 51 can be electrically connected with the single ground internal lead 1. Therefore, a ground voltage serving as a reference potential can be supplied to the semiconductor chip 5 from the two ground pads 51.

Accordingly, an increase in the ground voltage due to an internal wiring resistance of the semiconductor chip 5 can be suppressed. Thus, a reduction in performance of the package device can be suppressed.

Further, when the internal lead 1 is used for a power supply voltage, a reduction in the power supply voltage serving as a driving voltage for the semiconductor chip can be suppressed.

Furthermore, the two ground pads 51 provided on the semiconductor chip 5 can be connected with the single ground internal lead 1. Therefore, each ground internal lead 1 does not have to be provided for each ground pad.

Therefore, the number of internal leads can be reduced, and arrangement of the lead wiring lines in the lead frame 10 can be simplified.

Moreover, this ground internal lead 1 also functions as a suspender pin (a tie bar). Therefore, arrangement of the suspender pin additionally provided in the lead frame does not have to be taken into consideration to arrange the lead wiring lines, thus further simplifying arrangement of the lead wiring lines.

It is to be noted that, when the semiconductor chip 5 is mounted on the lead frame 10, it is arranged on the ground internal lead 1 and the signal wiring internal leads 2 through an insulating layer, e.g., an insulative adhesive. Additionally, these internal leads 1 and 2 support the semiconductor chip 5.

That is because the structure of the lead frame according to the embodiment of the present invention does not have a definite part corresponding to a tab (a die pad) provided to support the semiconductor chip.

Therefore, as shown in FIG. 1, when the ground internal lead 1 has the T-shaped structure, the ground internal lead 1 supports the semiconductor chip as a suspender pin extending in three directions. However, in this case, this structure is unstable to support the semiconductor chip.

Accordingly, it is desirable that the ground internal lead 1 functions as a suspender pin extending in four directions to support the semiconductor chip 5 like the H-shaped structure depicted in FIG. 2.

As explained above, according to the lead frame used in the embodiment of the present invention, the ground or power supply voltage internal lead has the wiring portion extending along a direction parallel to the one side of the semiconductor chip on which the ground or power supply pads are provided.

When the ground or power supply voltage pads are connected with this wiring portion, an increase in a ground voltage or a reduction in a power supply voltage due to an internal wiring resistance of the semiconductor chip can be suppressed.

Therefore, according to the embodiment of the present invention, a reduction in performance of the package device can be suppressed.

Furthermore, adopting the structure of the ground or power supply voltage internal lead enables reducing the number of lead wiring lines or the number of pins, thus simplifying arrangement of the lead wiring lines in the lead frame.

### (B) EXAMPLE p An example of a package device using the lead frame will now be explained hereinafter.

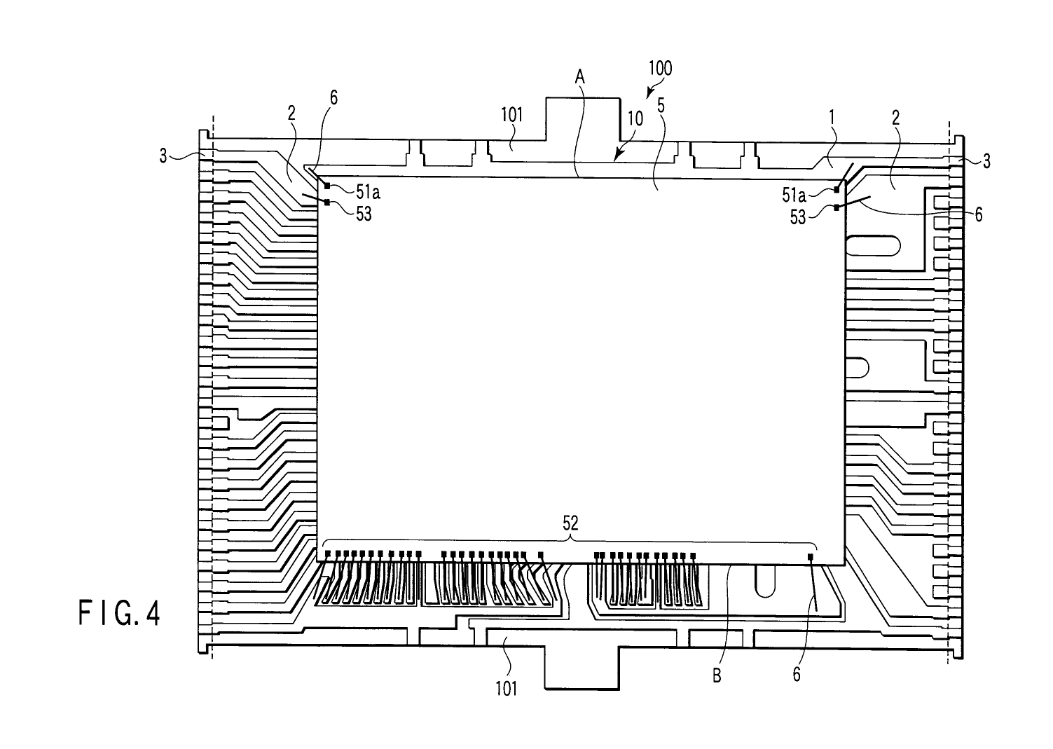

FIGS. 3 and 4 are plan views in which package materials on an upper surface and a lower surface of a lead frame in a package device are removed. FIG. 3 is a plan view seen from a side where a semiconductor chip is not provided (which will be referred to as a lead frame side hereinafter), and FIG. 4 is a plan view seen from a side where the semiconductor chip is provided (which will be referred to as a semiconductor chip side hereinafter).

It is to be noted that an internal lead which is a characteristic of the example according to the present invention is a ground internal lead.

A semiconductor chip 5 is mounted on a lead frame 10, and they are sealed by an insulative package material 10 and mounted as a package device 100 on an electronic device. The lead frame 10 is formed of an alloy containing copper (Cu) or iron (Fe). The semiconductor chip 5 is a consolidated chip having a memory chip such as a flash memory or a dynamic random access memory (DRAM), an LSI chip, or embedded chip which an LSI and a memory are formed in the same chip.

As shown in FIG. 3, the lead frame 10 includes a ground internal lead 1 and a plurality of signal wiring internal leads 2 arranged in the package 100 and external leads 3 which are connected with these internal leads 1, 2 and function as external terminals.

A ground voltage serving as a reference voltage is applied to the ground internal lead 1 from the outside through the external leads 3. Furthermore, this ground voltage is supplied to the inside of the semiconductor chip 5 through ground pads 51a of the semiconductor chip 5. This internal lead 1 also functions as a suspender pin (a tie bar).

The plurality of signal wiring internal leads 2 are provided to input/output control signals or data signals between an external device (not shown) and the semiconductor chip through the external leads 3. It is to be noted that, when the internal lead 1 is used for the ground like this example, one of the plurality of internal leads 2 is used for supply of a power supply voltage.

Moreover, as shown in FIG. 4, the semiconductor chip 5 is mounted on the lead frame 10. The semiconductor chip 5 is disposed on the internal leads 1 and 2 through an insulating layer (not shown), e.g., an insulative adhesive.

The ground pads 51a and a plurality of pads 52 and 53 are provided on the semiconductor chip 5.

The ground pads 51a are provided along one side A of the semiconductor chip 5. Additionally, the ground pads 51a are provided on both ends of this side A one by one, for example.

The ground pads 51a are electrically connected with the ground internal lead 1 through wires 6 based on wire bonding.

The plurality of pads 52 and 53 are used for the control signals and the input/output data signals, and provided on the semiconductor chip 5. Further, one of these pads 52 and 53 is used for the power supply voltage.

Of these pads, the pads (third pads) 52 are provided to be biased toward one side B facing side A where the ground pads 51a are provided.

The plurality of pads 52 and 53 are connected with respective corresponding lead wiring lines in the plurality of signal wiring internal leads 2 through the wires 6.

As shown in FIG. 4, the ground internal lead 1 has a wiring portion parallel to side A where the ground pads 51a are provided. Further, the semiconductor chip 5 is mounted on the lead frame 10 in such a manner that the side A where the ground pads 51a are provided vertically overlaps the wiring portion parallel to the side A.

Therefore, the two ground pads 51a provided on the semiconductor chip 5 along side A can be connected with the single ground external lead 1. As a result, the ground voltage serving as the reference potential of the semiconductor chip 5 can be supplied from the two ground pads 51a.

Accordingly, an increase in the ground voltage in the semiconductor chip 5 can be suppressed.

Furthermore, when the internal lead 1 is used for the power supply voltage, a reduction in the power supply voltage in the semiconductor chip 5 can be suppressed.

Moreover, the two ground pads 51a provided on the semiconductor chip 5 can be connected with the single ground internal lead 1. Therefore, the ground internal lead 1 does not have to be provided in accordance with each ground pad 51a.

Thus, the number of internal leads can be reduced, and arrangement of the lead wiring lines in the lead frame 10 can be simplified.

Additionally, when the structure of the ground internal lead 1 is adopted, one end of each signal wiring internal lead 2 connected with each of the plurality of pads (the third pads) 52 provided on side B can be readily arranged along side B through the lower surface of the semiconductor chip 5. Therefore, arranging the wires at the time of connection using wire bonding can be also facilitated.

As explained above, in the lead frame on which the semiconductor chip is mounted, the ground or power supply voltage internal lead has the wiring portion parallel to the one side of the semiconductor chip on which the ground and power supply voltage pads are provided. Additionally, the semiconductor chip is mounted on the lead frame in such a manner that this wiring portion overlaps the one side of the semiconductor chip where the ground and power supply voltage pads are provided.

As a result, an increase in the ground voltage and a reduction in the power supply voltage in the semiconductor chip can be suppressed. Therefore, a reduction in performance of the package device can be restrained.

Further, arrangement of the lead wiring lines in the lead frame can be simplified.

### (C) MODIFICATIONS

### (1) First Modification

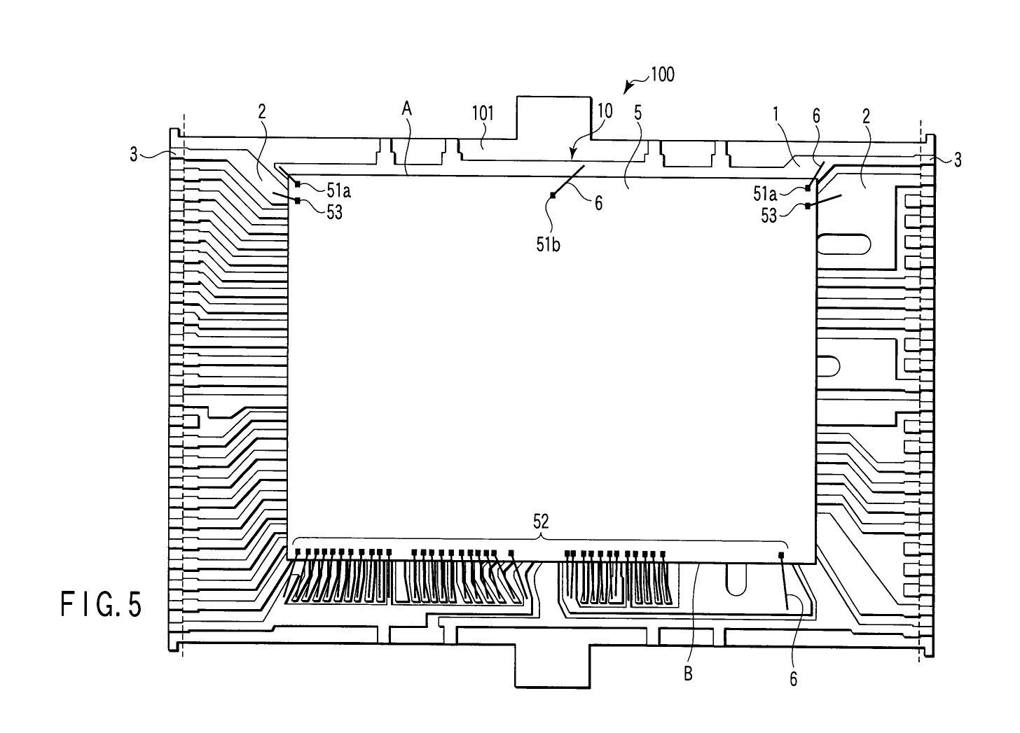

FIG. 5 is a plan view of a semiconductor chip side according to this modification.

It is to be noted that an example of a ground internal lead will be explained like the above description. Like reference numbers denote members equal to those in the example, thereby omitting a detailed explanation thereof.

This modification is characterized by including the two ground pads 51a explained in the above example as well as a ground pad 51b provided along a side A where these pads are provided.

The ground pad 51b is connected with a ground internal lead 1 through a wire 6 based on wire bonding like the ground pads 51a.

It is to be noted that the newly provided ground pad 51b is not restricted to one in number and a plurality of ground pads 51b may be provided.

Therefore, providing two or more ground pads along side A of a semiconductor chip enables efficiently supplying a ground voltage into the semiconductor chip, thereby further suppressing an increase in the ground voltage due to an internal wiring resistance of the semiconductor chip 5.

Furthermore, even if the two or more ground pads are provided along side A, the number of ground internal leads may be one since the ground internal lead 1 has a wiring portion extending along a direction parallel to side A.

Therefore, when the new ground pad is provided on side A, a new ground internal lead associated with this ground pad does not have to be provided.

Accordingly, an increase in the ground voltage and a reduction in the power supply voltage caused due to the internal wiring resistance of the semiconductor chip can be suppressed, and a decrease in performance of a package device can be restrained.

Moreover, arrangement of internal leads in the lead frame can be simplified.

### (2) Second Modification

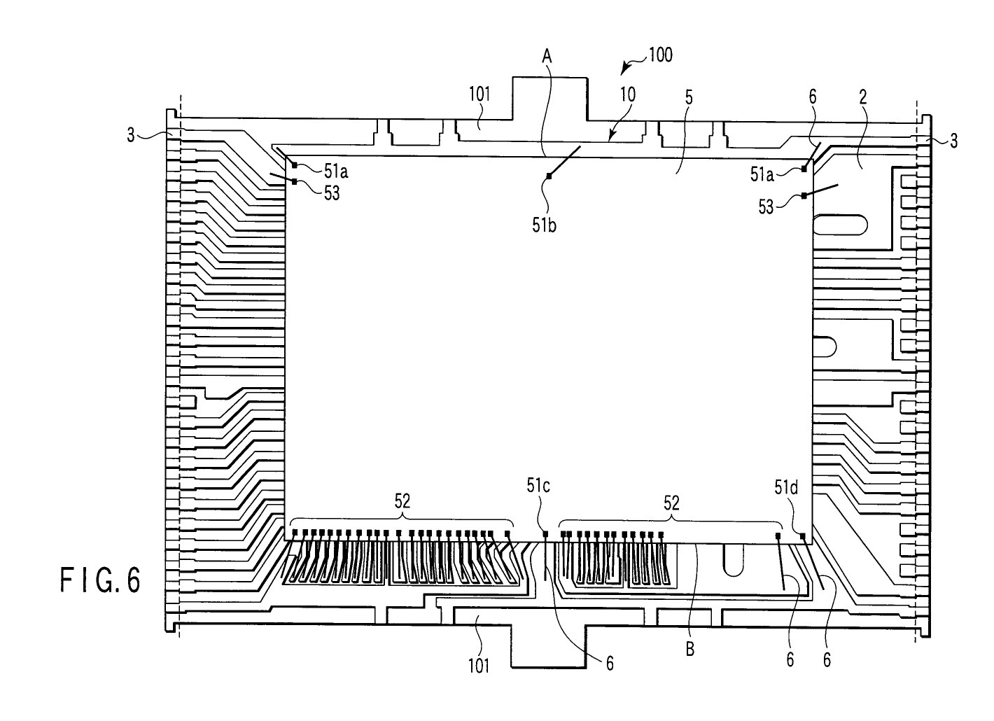

FIG. 6 is a plan view of a semiconductor chip side according to this modification.

An example of a ground internal lead will be explained like the above description. It is to be noted that like reference numbers denote members equal to those in the above example, thereby omitting a detailed explanation thereof.

As shown in FIG. 6, a semiconductor chip 5 also has a plurality of pads on a side B facing a side A.

A ground internal lead 1 has a wiring portion extending in a direction along which a part of this internal lead crosses side B.

Therefore, ground pads (second pads) 51c and 51d are further provided on the semiconductor chip 5 on side B facing side A so that these pads 51c and 51d can be connected with the ground internal lead 1 extending along a direction of side B.

Specifically, ground pads 51a and 51b are provided along side A of the semiconductor chip 5. Additionally, the ground pads 51c and 51d are provided in addition to a plurality of pads (third pads) 52 provided along side B of the semiconductor chip facing side A.

As explained above, the ground internal lead 1 has the wiring portion extending along side A and the wiring portion extending in the direction crossing side B.

The ground pad 51c is electrically connected with the wiring portion crossing side B in the ground internal lead 1 arranged toward the direction of side B based on wire bonding. Further, the ground pad 51d is electrically connected with the wiring portion extending in the direction parallel to side B in the ground internal lead 1 arranged toward the direction of side B based on wire bonding.

As a result, a ground voltage can be also supplied to a region apart from side A, such as side B of the semiconductor chip. Therefore, an increase in the ground voltage caused due to an internal wiring resistance of the semiconductor chip 5 can be suppressed.

Further, providing the single ground internal lead with respect to the ground pads 51a, 51b, 51c, and 51d provided on side A and side B of the semiconductor chip 5 can suffice. Therefore, arrangement of the lead wiring lines in the lead frame does not become complicated, and it can be simplified.

As explained above, an increase in the ground voltage and a reduction in the power supply voltage in the semiconductor chip can be further suppressed.

Therefore, a reduction in performance of the package device can be restrained.

Furthermore, arrangement of the internal leads in the lead frame can be simplified.

### 3. Others

According to examples of the present invention, arrangement of the lead wiring lines in the lead frame on which the semiconductor chip is mounted can be simplified while suppressing a reduction in performance caused due to an internal wiring resistance of the semiconductor chip.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a first internal lead provided in a lead frame; and
a semiconductor chip which is mounted on the lead frame and has a plurality of first pads provided along a first side,
wherein the first internal lead has a first wiring portion extending in a direction parallel to the first side,
the first side is arranged to vertically overlap the first wiring portion, and
the first pad is connected with the first wiring portion.

2. The semiconductor device according to claim 1, wherein the first internal lead is used for a ground or a power supply voltage.

3. The semiconductor device according to claim 1, wherein the first pads are used for a ground or a power supply voltage.

4. The semiconductor device according to claim 1, wherein the plurality of first pads are provided at both ends of the first side of the semiconductor chip at least one by one.

5. The semiconductor device according to claim 1, wherein the semiconductor chip further has at least one second pad provided along a second side facing the first side,
the first internal lead has a second wiring portion extending in a direction crossing the second side, and
the second pad is connected with the second wiring portion.

6. The semiconductor device according to claim 5, wherein the first and second pads are respectively connected with the first and second wiring portions by using bonding wires.

7. The semiconductor device according to claim 1, wherein the lead frame further has a plurality of second internal leads,
the semiconductor chip further has a plurality of third pads along the second side, and
one end of each of the plurality of second internal leads connected with the plurality of third pads is provided along the second side through a lower surface of the semiconductor chip.

8. The semiconductor device according to claim 7, wherein the plurality of second internal leads are used for signal wiring lines.

9. The semiconductor device according to claim 7, wherein the semiconductor chip is arranged on the first and second internal leads through an insulating layer, and
the lead frame does not have a tab which is used to arrange the semiconductor chip.

10. The semiconductor device according to claim 7, wherein the plurality of third pads are respectively connected with the plurality of second internal leads by using bonding wires.

11. The semiconductor device according to claim 7, wherein the lead frame further has external leads serving as external terminals which are respectively connected with the first and second internal leads.

12. The semiconductor device according to claim 11, further comprising an insulative package material which seals the first and second internal leads and the semiconductor chip mounted on the first and second internal leads to expose the external leads.

13. The semiconductor device according to claim 1, wherein the first internal lead has a T-shaped structure and arranged in the lead frame.

14. The semiconductor device according to claim 1, wherein the first internal lead has an H-shaped structure are arranged in the lead frame.

15. The semiconductor device according to claim 7, wherein the second internal lead has an L-shaped structure and arranged in the lead frame.

16. The semiconductor device according to claim 9, wherein the insulating layer is an insulative adhesive.

17. The semiconductor device according to claim 1, wherein the lead frame is formed of an alloy containing copper or iron.

18. The semiconductor device according to claim 1, wherein the semiconductor chip is a memory chip.

19. The semiconductor device according to claim 1, wherein the semiconductor chip is an LSI chip.

20. The semiconductor device according to claim 1, wherein the semiconductor chip is an embedded chip.
